(19) United States
(12) Patent Application Publication
(10) Pub. No.: US 2024/0403679 A1
(43) Pub. Date: Dec. 5, 2024

(54) QUANTUM CIRCUIT DESIGN METHOD FOR TOFFOLI DEPTH REDUCTION

(71) Applicant: ELECTRONICS AND TELECOMMUNICATIONS RESEARCH INSTITUTE, Daejeon (KR)

(72) Inventor: Jong-Heon LEE, Seoul (KR)

(73) Assignee: ELECTRONICS AND TELECOMMUNICATIONS RESEARCH INSTITUTE, Daejeon (KR)

(21) Appl. No.: 18/403,884

(22) Filed: Jan. 4, 2024

(30) Foreign Application Priority Data
May 30, 2023 (KR) 10-2023-0069326

(51) Int. Cl. G06N 10/20; G06F 30/30

(52) U.S. Cl. CPC G06N 10/20; G06F 30/30

(57) ABSTRACT

Disclosed herein is a method for quantum circuit design for Toffoli-depth reduction. The method includes generating an in-place version of an input quantum circuit having a minimized Toffoli-count based on reversible function blocks forming a quantum circuit, detecting permutations corresponding to respective mixed polarity Toffoli gates included in the input quantum circuit, searching for a pair of gates capable of being processed in parallel, among the mixed polarity Toffoli gates, based on the permutations, and generating an output quantum circuit, the Toffoli-depth of which is reduced compared to the input quantum circuit, by changing the positions of the mixed polarity Toffoli gates such that the pair of gates is processed in parallel based on work qubits.

### CROSS REFERENCE TO RELATED APPLICATION

This application claims the benefit of Korean Patent Application No. 10-2023-0069326, filed May 30, 2023, which is hereby incorporated by reference in its entirety into this application.

### BACKGROUND OF THE INVENTION

### 1. Technical Field

The present disclosure relates generally to technology for quantum circuit design for reducing a Toffoli-depth, and more particularly to technology for quantum circuit design for reducing a Toffoli-depth that is one of time cost metrics in a quantum circuit formed based on a set of NOT, CNOT, and Toffoli (NCT) gates.

### 2. Description of the Related Art

In order to design a time-efficient quantum circuit, it is essential to reduce a Toffoli-depth, which is the number of nonparallel processing of Toffoli gates. A Toffoli gate is a composite gate in which various basic gates in a Clifford+T gate set are used. When the Toffoli-depth is reduced, a time-efficient quantum circuit may be designed.

### DOCUMENTS OF RELATED ART

(Patent Document 1) Korean Patent Application Publication No. 10-2019-0007375, published on Jan. 22, 2019 and titled “Quantum circuit for phase shift of target qubit based on control qubit”.

### SUMMARY OF THE INVENTION

An object of the present disclosure is to reduce the Toffoli-depth of a given in-place version of a quantum circuit, thereby converting the quantum circuit into a more time-efficient in-place version of a quantum circuit.

Another object of the present disclosure is to enable ancilla (work) qubits for assisting an operation process to be initialized in an in-place version of a quantum circuit and to provide the initialized work qubits to a subsequent circuit operation, thereby more efficiently using the work qubits.

In order to accomplish the above objects, a method for quantum circuit design according to the present disclosure includes generating an in-place version of an input quantum circuit having a minimized Toffoli-count based on reversible function blocks forming a quantum circuit, detecting permutations corresponding to respective mixed polarity Toffoli gates included in the input quantum circuit, searching for a pair of gates capable of being processed in parallel, among the mixed polarity Toffoli gates, based on the permutations, and generating an output quantum circuit, the Toffoli-depth of which is reduced compared to the input quantum circuit, by changing the positions of the mixed polarity Toffoli gates such that the pair of gates is processed in parallel based on work qubits.

Here, the number of work qubits may be set in consideration of the number of qubit positions common to the pair of gates.

Here, searching for the pair of gates may comprise converting the permutation into a product of transpositions and searching for the pair of gates based on the product of the transpositions.

Here, generating the output quantum circuit may include adding a first-type CNOT gate in a section in which the pair of gates is processed in parallel in order to input information required for forming the permutation to the work qubits; and adding a second-type CNOT gate for initialization of the work qubits.

Here, the work qubits may be initialized through the second-type CNOT gate after an operation by the mixed polarity Toffoli gates is completed.

Here, the in-place version of the input quantum circuit may be generated by inputting index values of the respective reversible function blocks to data qubits.

Here, in a quantum circuit system configured to include the output quantum circuit, initialized work qubits may be provided for an operation arranged after the output quantum circuit.

Also, a method for quantum circuit design according to an embodiment of the present disclosure includes generating an in-place version of an input quantum circuit based on reversible function blocks forming a quantum circuit, detecting permutations corresponding to respective mixed polarity Toffoli gates included in the input quantum circuit, and generating an output quantum circuit by changing arrangement of the mixed polarity Toffoli gates based on the permutations and work qubits such that a Toffoli-depth is minimized. Here, when the input quantum circuit is generated, an increase in a Toffoli-count is allowed.

Here, generating the output quantum circuit may include converting the permutation into a product of transpositions and cancelling out transpositions capable of being canceled out in the product of the transpositions.

Here, generating the output quantum circuit may comprise generating the output quantum circuit in consideration of at least one of four design types for increasing time efficiency or space efficiency.

Here, the four design types may include a first design type that minimizes the Toffoli-depth regardless of the number of work qubits, a second design type that repeatedly generates function values of the reversible function blocks in consideration of the number of data qubits and the number of work qubits, a third design type that makes the same permutation repeated in consideration of the permutations and a flow of data information, and a fourth design type that additionally reduces the Toffoli-count in the output quantum circuit.

Here, the second design type may be configured such that the function values are generated (n+m)/m times based on n data qubits and m work qubits.

Here, the fourth design type may be configured such that, when the number of work qubits is equal to or greater than twice the number of data qubits, the work qubits are initialized using a CNOT gate and an intermediate value is input to the initialized work qubits so that the CNOT gate is converted to the permutation corresponding to the mixed polarity Toffoli gate.

Here, when the input quantum circuit corresponds to a Measurement-Based Quantum Computation (MBQC) model, the output quantum circuit may be generated by further considering two MBQC-based design types.

Here, the two MBQC-based design types may include an MBQC-based first design type configured to make an output value pair of an AND gate different from an input value pair of an AND^{†} gate and an MBQC-based second design type configured to generate an output value using an intermediate value generated using an AND gate.

Here, the in-place version of the input quantum circuit may be generated by inputting index values of the respective reversible function blocks to data qubits.

Here, in a quantum circuit system configured to include the output quantum circuit, initialized work qubits may be provided for an operation arranged after the output quantum circuit.

### BRIEF DESCRIPTION OF THE DRAWINGS

The above and other objects, features, and advantages of the present disclosure will be more clearly understood from the following detailed description taken in conjunction with the accompanying drawings, in which:

FIG. 1 is a view illustrating an example of an NCT gate set;

FIG. 2 is a view illustrating an example of a mixed polarity Toffoli gate;

FIG. 3 is a flowchart illustrating a method for quantum circuit design for Toffoli-depth reduction according to an embodiment of the present disclosure;

FIG. 4 is a view illustrating the quantum circuit design method illustrated in FIG. 3 in more detail;

FIGS. 5 to 6 are views illustrating an example of a chi function quantum circuit used as an input quantum circuit according to the present disclosure;

FIG. 7 is a view illustrating an example of an in-place version of a quantum circuit that is designed to reduce a Toffoli-depth while maintaining a Toffoli-count according to the present disclosure;

FIG. 8 is a view illustrating another example of an in-place version of a quantum circuit that is designed to reduce a Toffoli-depth while maintaining a Toffoli-count according to the present disclosure;

FIG. 9 is a flowchart illustrating a method for quantum circuit design for Toffoli-depth reduction according to another embodiment of the present disclosure;

FIG. 10 is a view illustrating the quantum circuit design method illustrated in FIG. 9 in more detail;

FIGS. 11 to 13 are views illustrating an example of an in-place version of a quantum circuit that is designed to reduce a Toffoli-depth when an increase in a Toffoli-count is allowed according to the present disclosure;

FIG. 14 is a view illustrating an example of an AND gate;

FIG. 15 is a view illustrating an example of an AND gate; and

FIG. 16 is a view illustrating an example of an in-place version of a quantum circuit that is designed to reduce a Toffoli-depth using Measurement-Based Quantum Computation (MBQC) when an increase in a Toffoli-count is allowed according to the present disclosure.

### DESCRIPTION OF THE PREFERRED EMBODIMENTS

The present disclosure will be described in detail below with reference to the accompanying drawings. Repeated descriptions and descriptions of known functions and configurations which have been deemed to unnecessarily obscure the gist of the present disclosure will be omitted below. The embodiments of the present disclosure are intended to fully describe the present disclosure to a person having ordinary knowledge in the art to which the present disclosure pertains. Accordingly, the shapes, sizes, etc. of components in the drawings may be exaggerated in order to make the description clearer.

In the present specification, each of expressions such as “A or B”, “at least one of A and B”, “at least one of A or B”, “A, B, or C”, “at least one of A, B, and C”, and “at least one of A, B, or C” may include any one of the items listed in the expression or all possible combinations thereof.

The technology to be proposed in the present disclosure may be broadly classified depending on whether an increase in a Toffoli-count, which is the number of Toffoli gates used in a quantum circuit, is allowed. In the present disclosure, both an input circuit and an output circuit are in-place version quantum circuits, desired function values may be output from data qubits, and all work (ancilla) qubits may be initialized in the quantum circuit.

Here, the ‘in-place version’ may mean that function values are represented in data qubits, rather than work qubits, so all of the work qubits are initialized after the function operation is finished. For reference, a method of representing function values in work qubits is called an out-of-place version. Therefore, when a quantum circuit is designed as an in-place version, work qubits may be more effectively used for a subsequent operation.

In order to form an in-place version of a quantum circuit having a reduced Toffoli-depth, more quantum resources, such as work qubits, are required, so it is impossible to make a circuit having a reduced Toffoli-depth using an existing optimization technique.

Accordingly, the present disclosure proposes a quantum circuit design method that deals with a trade-off between the space complexity of a quantum circuit based on an NCT gate set and the time complexity thereof. The overall description is made taking a chi function of an SHA3-256 hash function algorithm as an example.

The present disclosure relates to technology for reducing the Toffoli-depth of a given in-place version of a quantum circuit by adding initialized work qubits, thereby returning a time-efficient in-place version quantum circuit.

Generally, the composition of a quantum circuit may be attempted based on a set of NOT, CNOT, controlled-V and controlled-V+ (NCV) gates or a set of NOT, CNOT, and Toffoli (NCT) gates. Here, NCT gates invert or flip the state of one qubit (bit-flip) depending on a condition.

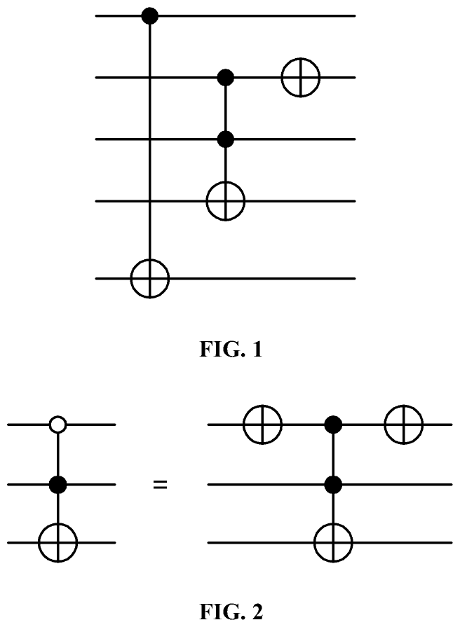

Referring to FIG. 1, a CNOT gate, a Toffoli gate, and a NOT gate are illustrated from the left. For example, the CNOT gate illustrated in FIG. 1 may invert the state of a qubit on a target line when the state of a qubit on one control line is TRUE (1), the Toffoli gate may invert the state of a qubit on a target line when all of the states of qubits on two control lines are TRUE (1), and the NOT gate may unconditionally invert the state of a qubit on a line on which the gate is placed.

When a quantum circuit is designed based on such NCT gates, the Toffoli gate is most costly to design, and it takes a large amount of time to execute.

For example, because a T gate and a T^{†} gate are used for designing a Toffoli gate, the Toffoli gate is more costly to design than other gates and takes a longer time to execute in a Fault-Tolerant Quantum Computing (FTQC) model. That is, a Toffoli-count, which is the number of T gates and T^{†} gates, and a Toffoli-depth, which is the depth formed by these gates in a quantum circuit (the number of times the T gate or the T^{†} gate is processed in a nonparallel manner), are very important cost metrics in the FTQC model.

Therefore, in order to design a space-efficient or time-efficient quantum circuit, it is essential to reduce a Toffoli-count and a Toffoli-depth, which are cost metrics related to Toffoli gates.

For reference, because the flow of time in a quantum circuit is from left to right, a gate located on the left side is activated first. Also, when qubits correspond to given information, the least significant bit (LSB) corresponds to a qubit located at the top of the circuit, and the most significant bit (MSB) corresponds to a qubit located at the bottom of the circuit. That is, in the quantum circuit, bit positions sequentially increase from top to bottom.

Meanwhile, a Toffoli gate can be activated in another condition by using a NOT gate, and this gate is referred to as a mixed polarity Toffoli gate.

For example, the mixed polarity Toffoli gate illustrated in FIG. 2 inverts the state of a qubit on the third control line corresponding to a target line when the state of a qubit on the first control line, which corresponds to the LSB, is FALSE (0) and when the state of a qubit on the second control line is TRUE (1).

When a mixed polarity Toffoli gate includes three or more control lines, it may be referred to as a Mixed Polarity Multiple Controlled Toffoli (MPMCT) gate. An NCT gate set including an MPT gate is used as the main matter in a Toffoli-depth reduction method. Hereinafter, a Toffoli gate and an MPT gate are used interchangeably with each other for convenience of description.

Meanwhile, qubits may be called different names depending on how they are used when an operation is performed in a quantum circuit.

First, data qubits may represent Boolean variables used to express a (reversible) Boolean function. For example, when a 5-variable Boolean function is present, five qubits may be data qubits in a quantum circuit. That is, from the front part of the quantum circuit, data qubits may correspond to qubits containing information about the Boolean variables.

Qubits that are not data qubits are called work qubits or ancilla qubits. The work qubits are generally initialized to ‘0’ in the front part of a quantum circuit. Also, the work qubits are initialized through an uncomputation (clearing) operation after a specific operation is performed in the quantum circuit, and the initialized clean work qubits are called clean work qubits (CWQs). When uncomputation cannot be performed, the work qubits cannot be used for a subsequent operation in the circuit, so they called garbage qubits or Dirty Borrowed Qubits (DBQs). Here, in order to use such work qubits that cannot be initialized, it is necessary to add a specific operation to the quantum circuit, which complicates the design of the circuit.

Also, in the present disclosure, permutation group theory and Boolean algebra are used for quantum circuit design for Toffoli-depth reduction. The permutation group theory is the concept emerged early in modern algebra, and is used for quantum reversible function synthesis, or the like in previous studies.

Here, a ‘permutation’ refers to a one-to-one correspondence function. For example, when 1 and 2 are paired with each other and each of the remaining elements is paired with itself in a domain and a codomain, each having a size of n, the permutation sigma (σ) may be expressed as shown in Equation (1) below:

$$σ = ( \begin{matrix}1 & 2 & 3 & 4 & … & n \\ 2 & 1 & 3 & 4 & … & n\end{matrix} ) = ( \begin{matrix}1 & 2\end{matrix} ) ∈ {S}_{n} \qquad ( 1 )$$

Referring to Equation (1), when the size of each of the domain and the codomain is n, a set of permutations is represented as Sₙ.

Here, when set A is {1, 2, . . . , n} and the permutation σ is given, it corresponds to [a]={σⁿ(a)∈A|n∈Z}, and this is called an orbit of σ.

Also, when a permutation σ has at most one orbit and when the orbit includes one or more elements, the permutation σ is called a cycle. Here, the cycle σ is an orbit having the largest size, among the orbits of the permutation.

For example, it may be assumed that a permutation σ is given, as shown in Equation (2) below:

$$σ = ( \begin{matrix}1 & 2 & 3 & 4 & 5 & 6 \\ 2 & 3 & 1 & 5 & 4 & 6\end{matrix} ) = ( \begin{matrix}1 & 2 & 3\end{matrix} ) ( \begin{matrix}4 & 5\end{matrix} ) ( 6 ) ∈ {S}_{6} \qquad ( 2 )$$

Here, a cycle having a length 2 is referred to as a transposition, and a cycle of length 1 is referred to as an identity permutation. Also, a permutation that can be expressed as a product of an odd number of transpositions is referred to as an odd permutation, and a permutation that can be expressed as a product of an even number of transpositions is referred to as an even permutation.

When given two cycles have no common element, the two cycles are disjoint. Here, the reason why disjoint cycles are important is that, when n (the size of the domain and the codomain) is equal to or greater than 3, a set of permutations, Sₙ, is a non-abelian group. That is, the two disjoint cycles are not allowed to swap their positions.

For example, (1 2 3) and (3 4) in S₆ in Equation (2) are not commutative, and the commutative property does not hold therefor. That is, (1 2 3) (3 4) differs from (3 4) (1 2 3). Here, an operation for composition of multiple cycles starts from the rightmost cycle, and this is the same as the operation sequence of a composite function. Accordingly, in the case of (1 2 3) (3 4), 3 corresponds to 4, but in the case of (3 4) (1 2 3), 3 corresponds to 1.

Here, the orbits of the permutation σ may be expressed as [1]=[2]=[3]={1,2,3}, [4]=[5]={4,5}, [6]={6}. Therefore, the permutation σ itself in Equation (2) is not a cycle, as described above, but the permutations forming the permutation σ, that is, (1,2,3), (4,5), and (6) are cycles, the lengths of which are 3, 2, and 1, respectively.

Also, when n (the size of the domain and the codomain) is equal to or greater than 2, all permutations σ∈Sₙ may be expressed as a product of transpositions. This may be proved as shown in Equation (3) below:

$$( {α}_{1} ) = ( {α}_{1} , {α}_{2} ) ( {α}_{1} , {α}_{2} ) \\ \begin{matrix}( {α}_{1} , {α}_{2} , … , {α}_{k} ) = ( {α}_{1} , {α}_{2} ) ( {α}_{2} , {α}_{3} ) … ( {α}_{k - 2} , {α}_{k - 1} ) ( {α}_{k - 1} , {α}_{k} ) \\ = ( {α}_{1} , {α}_{k} ) ( {α}_{1} , {α}_{k - 1} ) … ( {α}_{1} , {α}_{3} ) ( {α}_{1} , {α}_{2} )\end{matrix} \\ \begin{matrix}For k \geq 3 , ( {α}_{0} , {α}_{1} , … , {α}_{k} ) = ( {α}_{0} , {α}_{1} ) ( {α}_{k - 1} , {α}_{k} ) ( {α}_{1} , {α}_{2} … , {α}_{k - 2} , {α}_{k} ) \\ = ( {α}_{0} , {α}_{1} , {α}_{3} … , {α}_{k - 1} ) ( {α}_{0} , {α}_{1} ) ( {α}_{k - 1} , {α}_{k} )\end{matrix} \qquad ( 3 )$$

$$For k < l , ( k , l ) = ( k , k + 1 ) ( k + 1 , k + 2 ) … ( l - 2 , l - 1 ) ( l - 1 , l ) ( l - 2 , l - 1 ) … ( k , k + 1 )$$

When the definition and property of these permutations are used, the arrangement of NCT gates in a quantum circuit may be determined.

In the quantum circuit design method for Toffoli-depth reduction intended to be proposed in the present disclosure, all input/output circuits are in-place version reversible quantum circuits. Also, in the present disclosure, two cases are dealt with, as described above.

The first case is the case of reducing a Toffoli-depth while maintaining a Toffoli-count of an input circuit, and the second case is the case of increasing the Toffoli-count. Because all of the two cases require the help of more initialized work qubits, it is necessary to consider an uncomputation process for the respective work qubits. That is, when all operations are terminated in an output circuit, it is required to initialize all of the used work qubits.

When an increase in the Toffoli-count is allowed, more work qubits are expected to be used than when an increase in the Toffoli-count is not allowed, and more Toffoli gates are expected to be processed in parallel.

As an example for explaining the present disclosure, a chi (χ) function of an SHA3-256 hash function algorithm is used. Here, under the conditions of 0≤x, y<5, and 0≤z<64, the chi function may be performed as shown in Equation (4).

$$χ : S [ 64 x + 32 y + z ] ← S [ 64 x + 32 y + z ] ⊕ ( ( S [ 64 ( x + 1 ) + 320 y + z ] ⊕ 1 ) ∧ S [ 64 ( x + 2 ) + 320 y + z ] ) \\ S [ 64 ( 5 y + x ) + z ] = A [ x ] [ y ] [ z ] 0 \leq x , y < 5 , 0 \leq z < 64 \\ χ : A [ x ] [ y ] [ z ] ⊕ ( ( A [ x + 1 ] [ y ] [ z ] ⊕ 1 ) ∧ A [ x + 2 ] [ y ] [ z ] ) \qquad ( 4 )$$

In Equation (4), the state S indicates the case in which the function is expressed as a one-dimensional array, and array A indicates the case in which the function is expressed as a three-dimensional array.

In the SHA3-256 hash function algorithm, which deals with a bitstring configured with 1600 bits, 320 chi (χ) functions are simultaneously processed in parallel by dividing 1600 bits by 5 bits, as shown in Equation (4).

The present disclosure proposes a method for designing a quantum circuit having a reduced Toffoli-depth depending on whether an increase in a Toffoli-count is allowed when an in-place version of a chi function quantum circuit is given as an input circuit, as described above.

Also, when an increase in the Toffoli-count is allowed and when Measurement-Based Quantum Computation (MBQC) is used, ideas required for quantum circuit design are also proposed. Here, MBQC refers to a circuit design method that uses a measuring device in the quantum circuit.

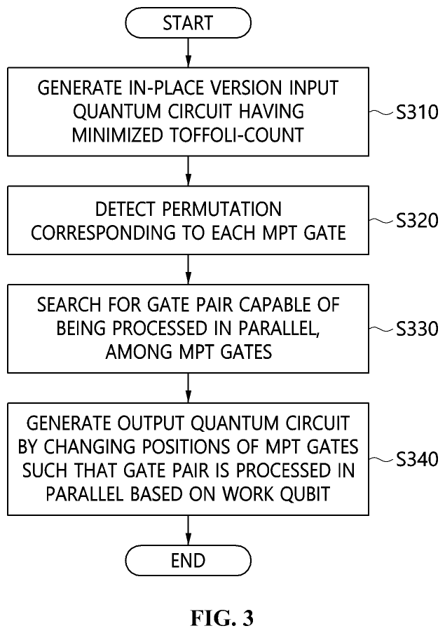

FIG. 3 is a flowchart illustrating a method for quantum circuit design for Toffoli-depth reduction according to an embodiment of the present disclosure.

Referring to FIG. 3, in the method for quantum circuit design for Toffoli-depth reduction according to an embodiment of the present disclosure, an in-place version of an input quantum circuit having a minimized Toffoli-count is generated based on reversible function blocks forming a quantum circuit at step S310.

Here, the index values of the respective reversible function blocks are input to data qubits, whereby an in-place version of an input quantum circuit may be generated.

Also, in the method for quantum circuit design for Toffoli-depth reduction according to an embodiment of the present disclosure, permutations corresponding to respective mixed polarity Toffoli gates included in the input quantum circuit are detected at step S320.

Also, in the method for quantum circuit design for Toffoli-depth reduction according to an embodiment of the present disclosure, a pair of gates capable of being processed in parallel, among the mixed polarity Toffoli gates, is searched for based on the permutations at step S330.

Here, each of the permutations is converted into a product of transpositions, and the pair of gates may be searched for based on the product of the transpositions.

The key idea to be used in the quantum circuit design method according to the present disclosure is that it is possible to represent NCT gates using a product of disjoint transpositions. That is, in a quantum circuit configured with n qubits, a k-controlled NOT (C^{k}NOT) gate, which is an MPMCT gate having k control lines, may be represented using a product of 2^{n-k-1} disjoint transpositions.

For example, when n qubits or bits are given, 2ⁿ numbers may be expressed using the n qubits or bits. Here, a C^{k}NOT gate is a gate on k+1 qubits. That is, because the number of qubits in which the C^{k}NOT gate is not involved is n−k−1, the gate may be represented using a product of 2^{n-k-}1 transpositions. The CNOT gate illustrated in FIG. 1 may correspond to a gate placed on the first qubit and the fifth qubit.

Here, assuming that the input states of the qubits are ‘00001’ (|00001>), the states after passing through the CNOT gate may become ‘10001’ (|10001>). Because gates are reversible in a quantum gate, the states may be converted in the reverse direction.

Referring to FIG. 1, it can be seen that, when the value of the LSB in the CNOT gate is TRUE (1), the value of the MSB is inverted. Here, because three qubits are not related to the CNOT gate, the CNOT gate may be represented using a product of eight disjoint transpositions.

Here, when each of the gates illustrated in FIG. 1 is represented using a product of transpositions, it may be as shown in Equation (5) below:

$$CNOT gate : ( 00001 , 10001 ) ( 00011 , 10011 ) ( 00101 , 10101 ) ( 00111 , 10111 ) ( 01001 , 11001 ) ( 01011 , 11011 ) ( 01101 , 11101 ) ( 01111 , 11111 ) = ( 1 , 17 ) ( 3 , 19 ) ( 5 , 21 ) ( 7 , 23 ) ( 9 , 25 ) ( 11 , 27 ) ( 13 , 29 ) ( 15 , 31 ) \\ Toffoli gate : ( 6 , 14 ) ( 7 , 15 ) ( 22 , 30 ) ( 23 , 31 ) \\ NOT gate : ( 0 , 2 ) ( 1 , 3 ) ( 4 , 6 ) ( 5 , 7 ) ( 8 , 10 ) ( 9 , 11 ) ( 12 , 14 ) ( 13 , 15 ) ( 16 , 18 ) ( 17 , 19 ) ( 20 , 22 ) ( 21 , 23 ) ( 24 , 26 ) ( 25 , 27 ) ( 28 , 30 ) ( 29 , 31 ) \qquad ( 5 )$$

Here, the Hamming distance between two elements of each transposition is 1. That is, when the two elements are expressed as bitstrings, they are different in only one position.

For example, referring to Equation (5), it can be seen that the elements of each of the transpositions forming the CNOT gate are different at the position of the MSB. That is, in the case of (1, 17), only the MSB positions thereof are different from each other.

For reference, when a quantum circuit is composed, swapping (SWAP gate) for changing the positions of qubits is occasionally used. In a quantum circuit configured with n qubits, swapping may be expressed as a product of 2ⁿ⁻² disjoint transpositions. A controlled-SWAP (CSWAP, Fedkin) gate having one control line may be represented using a product of 2ⁿ⁻³ disjoint transpositions. The Hamming distance between elements included in the transpositions forming these two gates is 2. Accordingly, when gates are represented using a product of disjoint transpositions in a quantum circuit formed based on NCT gates, the Hamming distance between elements of each transposition may be 1 or 2.

Also, in the method for quantum circuit design for Toffoli-depth reduction according to an embodiment of the present disclosure, the positions of the mixed polarity Toffoli gates are changed such that the pair of gates is processed in parallel based on the work qubits, whereby an output quantum circuit, the Toffoli-depth of which is reduced compared to the input quantum circuit, is generated at step S340.

Here, the number of work qubits may be set in consideration of the number of qubit positions common to the pair of gates.

Here, in order to input information required for forming the permutations to the work qubits, a first-type CNOT gate may be added to the section in which parallel processing is performed.

Here, a second-type CNOT gate for initializing the work qubits may be added.

Here, the work qubits may be initialized through the second-type CNOT gate after an operation by the mixed polarity Toffoli gates is completed.

Here, in a quantum circuit system configured to include the output quantum circuit, the initialized work qubits may be provided for an operation that is arranged after the output quantum circuit.

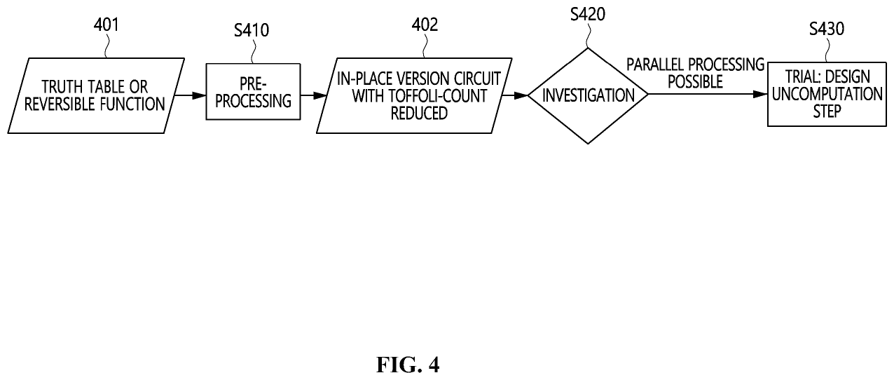

Here, the quantum circuit design method proposed through FIG. 3 relates to a method that does not increase a Toffoli-count, and this may be represented in detail as the flowchart in FIG. 4.

Referring to FIG. 4, an in-place version quantum circuit 402 having a minimized Toffoli-count may be generated for a given reversible function 401 by using a reversible circuit synthesis method and an optimization method presented in the previous studies at a preprocessing step (S410).

The generated quantum circuit 402 may be the input circuit of the method of FIG. 3. When a quantum circuit is generated based on an NCT gate set, if the given reversible function 401 is an odd permutation, one or more work qubits are required, but if the given reversible function 401 is an even permutation, the circuit may be designed without work qubits. That is, when the given reversible function 401 is an even permutation, the circuit may be designed as an ancilla-free circuit having no work qubits.

Subsequently, permutations corresponding to the respective NCT gates included in the input circuit 402 are detected, whereby a pair of gates capable of being processed in parallel, among the adjacent MPT gates (or Toffoli gates), may be found at step S420.

Typically, because disjoint permutations are commutative, parallel processing is possible. Here, if two gates capable of being processed in parallel share only a control line, parallel processing may be possible.

Subsequently, a number of work qubits may be added depending on the number of qubit positions common to the gates determined to be capable of being processed in parallel. Subsequently the positions of the Toffoli gates may be changed so as to reduce the Toffoli-depth at step S430.

Here, CNOT gates may be added in the parallel processing section. Also, CNOT gates may be installed for an uncomputation step, and information required for forming permutations may be input to the work qubits through these CNOT gates.

Here, the quantum circuit design process for Toffoli-depth reduction illustrated in FIG. 4 has some characteristics.

The first characteristic is that, even though a pair of Toffoli gates capable of being processed in parallel is present, when an uncomputation step is not completely designed, an in-place version of a quantum circuit having a reduced Toffoli-depth may not be generated.

The second characteristic is that uncomputation steps for work qubits added for parallel processing of the Toffoli gates may start at different times because operations by all gates are not performed at the same time.

The third characteristic is that, after the work qubits are used for parallel processing of the MPT gates, initialization may be attempted using only pieces of information contained in data qubits and other work qubits. That is, after a computation step for desired function values is finished, information of all work qubits should be initialized using the contained information.

The fourth characteristic is that the positions of the Toffoli gates may be changed due to addition of work qubits. Here, the positions of the MPT gates may also be changed at the uncomputation step as well as the computation step.

Hereinafter, taking a chi function of an SHA3-256 hash function algorithm as an example, a process of designing a chi function quantum circuit having a reduced Toffoli-depth using the method illustrated in FIG. 3 will be described in detail.

First, an in-place version of a chi function quantum circuit is generated through a preprocessing step. Here, because the chi function is a five-variable reversible Boolean function, it may be represented using a truth table like Table 1 below.

TABLE 1

| Input value | input value | Output value | Output value |
|---|---|---|---|
| x₄x₃x₂x₁x₀ | in decimal | x′₄x′₃x′₂x′₁x′₀ | in decimal |
| 00000 | 0 | 00000 | 0 |
| 00001 | 1 | 01001 | 9 |
| 00010 | 2 | 10010 | 18 |
| 00011 | 3 | 01011 | 11 |
| 00100 | 4 | 00101 | 5 |
| 00101 | 5 | 01100 | 12 |
| 00110 | 6 | 10110 | 22 |
| 00111 | 7 | 01111 | 15 |
| 01000 | 8 | 01010 | 10 |
| 01001 | 9 | 00011 | 3 |
| 01010 | 10 | 11000 | 24 |
| 01011 | 11 | 00001 | 1 |
| 01100 | 12 | 01101 | 13 |
| 01101 | 13 | 00100 | 4 |
| 01110 | 14 | 11110 | 30 |
| 01111 | 15 | 00111 | 7 |
| 10000 | 16 | 10100 | 20 |
| 10001 | 17 | 10101 | 21 |
| 10010 | 18 | 00110 | 6 |
| 10011 | 19 | 10111 | 23 |
| 10100 | 20 | 10001 | 17 |
| 10101 | 21 | 10000 | 16 |
| 10110 | 22 | 00010 | 2 |
| 10111 | 23 | 10011 | 19 |
| 11000 | 24 | 11010 | 26 |
| 11001 | 25 | 11011 | 27 |
| 11010 | 26 | 01000 | 8 |
| 11011 | 27 | 11001 | 25 |
| 11100 | 28 | 11101 | 29 |
| 11101 | 29 | 11100 | 28 |
| 11110 | 30 | 01110 | 14 |
| 11111 | 31 | 11111 | 31 |

When the chi function is expressed as a permutation based on the truth table illustrated in Table 1, Equation (6) may be acquired.

$$( 0 ) ( 1 , 9 , 3 , 11 ) ( 2 , 18 , 6 , 22 ) ( 4 , 5 , 12 , 13 ) ( 7 , 15 ) ( 8 , 10 , 24 , 26 ) ( 14 , 30 ) ( 16 , 20 , 17 , 21 ) ( 19 , 23 ) ( 25 , 27 ) ( 28 , 29 ) ( 31 ) \qquad ( 6 )$$

Here, it can be seen that the permutation in Equation (6) is formed of five 4-cycles, each having a length of 4, five transpositions, each having a length of 2, and two 1-cycles, each having a length of 1. Here, the 4-cycles may be expressed as a product of multiple transpositions in different ways. For example, one of the decompositions of each of the 4-cycles may be expressed as shown in Equation (7).

$$( 1 , 9 , 3 , 11 ) = ( 1 , 9 ) ( 3 , 11 ) ( 9 , 11 ) \\ ( 2 , 18 , 6 , 22 ) = ( 2 , 18 ) ( 6 , 22 ) ( 18 , 22 ) \\ ( 4 , 5 , 12 , 13 ) = ( 4 , 5 ) ( 12 , 13 ) ( 5 , 13 ) \\ ( 8 , 10 , 24 , 26 ) = ( 8 , 10 ) ( 24 , 26 ) ( 10 , 26 ) \\ ( 16 , 20 , 17 , 21 ) = ( 16 , 20 ) ( 17 , 21 ) ( 20 , 21 ) \qquad ( 7 )$$

That is, it can be seen that the chi function can be expressed as a product of the five transpositions in Equation (6) and the 15 transpositions in Equation (7) and that it is an even permutation composed of 20 transpositions.

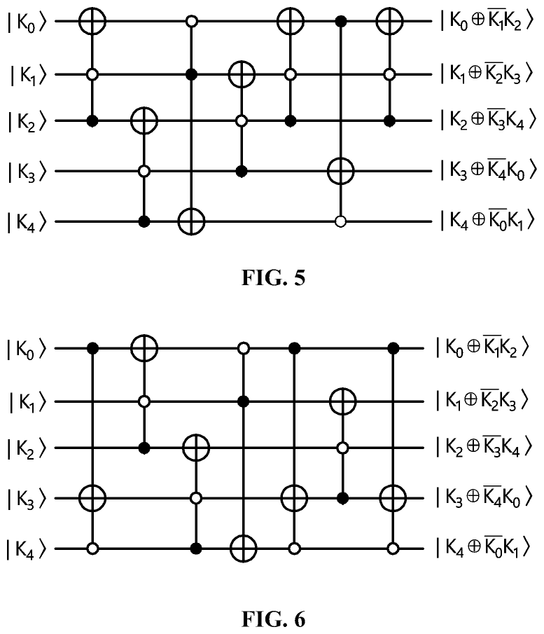

Here, an even permutation can be implemented as a quantum circuit without work qubits, and is known to be capable of being designed using only Toffoli gates and NOT gates. Accordingly, the even permutation may be designed as a quantum circuit such as that illustrated in FIG. 5 through the reversible circuit synthesis methods and various optimization methods proposed in the previous studies.

Referring to FIG. 5, a chi function quantum circuit having a Toffoli-count of 7 is illustrated. Using this circuit as the input quantum circuit of the present disclosure, the Toffoli-depth reduction method proposed in the present disclosure will be described below.

First, permutations corresponding to the mixed polarity Toffoli gates (MPT gates) used in the quantum circuit illustrated in FIG. 5 may be detected.

Here, the chi function quantum circuit illustrated in FIG. 5 includes seven MPT gates, and each of the MPT gates has a Hamming distance of 1. Accordingly, each of the seven MPT gates illustrated in FIG. 5 may be expressed as a product of disjoint transpositions, as shown in Equation (8):

$${1}^{st} MPT gate : ( 4 , 5 ) ( 12 , 13 ) ( 20 , 21 ) ( 28 , 29 ) \\ {2}^{nd} MPT gate : ( 16 , 20 ) ( 17 , 21 ) ( 18 , 22 ) ( 19 , 23 ) \\ {3}^{rd} MPT gate : ( 2 , 18 ) ( 6 , 22 ) ( 10 , 26 ) ( 14 , 30 ) \\ {4}^{th} MPT gate : ( 8 , 10 ) ( 9 , 11 ) ( 24 , 26 ) ( 25 , 27 ) \\ {5}^{th} MPT gate : ( 4 , 5 ) ( 12 , 13 ) ( 20 , 21 ) ( 28 , 29 ) \\ {6}^{th} MPT gate : ( 1 , 9 ) ( 3 , 11 ) ( 5 , 13 ) ( 7 , 15 ) \\ {7}^{th} MPT gate : ( 4 , 5 ) ( 12 , 13 ) ( 20 , 21 ) ( 28 , 29 ) \qquad ( 8 )$$

Referring to Equation (8), it can be seen that the chi function quantum circuit is represented using a total of 28 transpositions having a Hamming distance of 1. Here, because the permutation expressing the sixth MPT gate does not have 20, 21, 28, and 29, (20,21) (28,29) included in the fifth MPT gate and (20,21) (28,29) included in the seventh MPT gate may cancel out each other. Similarly, (4,5) (12,13) in the fifth MPT gate and (4,5) (12,13) in the first MPT gate may cancel out each other. That is, for the chi function that can be represented using 20 transpositions as shown in Equation (7), a quantum circuit is represented using a total of seven MPT gates by adding the eight transpositions that are canceled out.

Here, it can be seen that the order in which the gates are arranged is somewhat decided through Equation (8) and FIG. 5 because permutations are generally not commutative.

For example, because the permutations of the fourth MPT gate and the fifth MPT gate are disjoint, they are commutative, and this can also be seen in the quantum circuit illustrated in FIG. 5. That is, referring to FIG. 5, the fourth MPT gate and the fifth MPT gate share the same control line, but there is a point at which the gate activation conditions are opposite. Here, assuming that the positions of the fourth MPT gate and the fifth MPT gate are exchanged, it can be seen that the positions of the third MPT gate and the fifth MPT gate that is moved to the position of the fourth MPT gate can also be exchanged.

Also, the quantum circuit may be newly designed depending on the gate placed at the front of the quantum circuit. For example, when the sixth MPT gate illustrated in FIG. 5 is placed at the front of the quantum circuit, the quantum circuit may be designed in the form illustrated in FIG. 6.

Referring to the chi function quantum circuit illustrated in FIG. 5, because the first MPT gate, the fifth MPT gate, and the seventh MPT gate have the same arrangement, a total of five types of gates may be placed at the front of the corresponding quantum circuit. That is, when an in-place version of a quantum circuit implementing a chi function is designed without work qubits, at least 15 cases may be possible.

Here, referring to FIG. 5, it can be seen that parallel processing of MPT gates is impossible without adding work qubits, because the total number of qubits is 5 and MPT gates are 3-qubit gates. Therefore, it is essential to add work qubits in order to reduce the Toffoli-depth.

Here, among the MPT gates included in the chi function quantum circuit illustrated in FIG. 5, two pairs of gates may be processed in parallel. The first pair is a pair comprising the third MPT gate and the fifth MPT gate, and the second pair is a pair comprising the fourth MPT gate and the fifth MPT gate.

First, the process of generating an in-place version of a quantum circuit having a reduced Toffoli-depth by processing the pair comprising the third MPT gate and the fifth MPT gate in parallel according to the present disclosure will be described.

Here, the third MPT gate corresponds to a gate on the qubits having index values of 0, 1, and 4, and the fifth MPT gate corresponds to a gate on the qubits having index values of 0, 1, and 2. That is, because two indices are common to the third MPT gate and the fifth MPT gate, it is necessary to add at least two work qubits in order to process the third MPT gate and the fifth MPT gate in parallel. Also, the added work qubits have to receive data information using CNOT gates before the MPT gates are arranged in parallel.

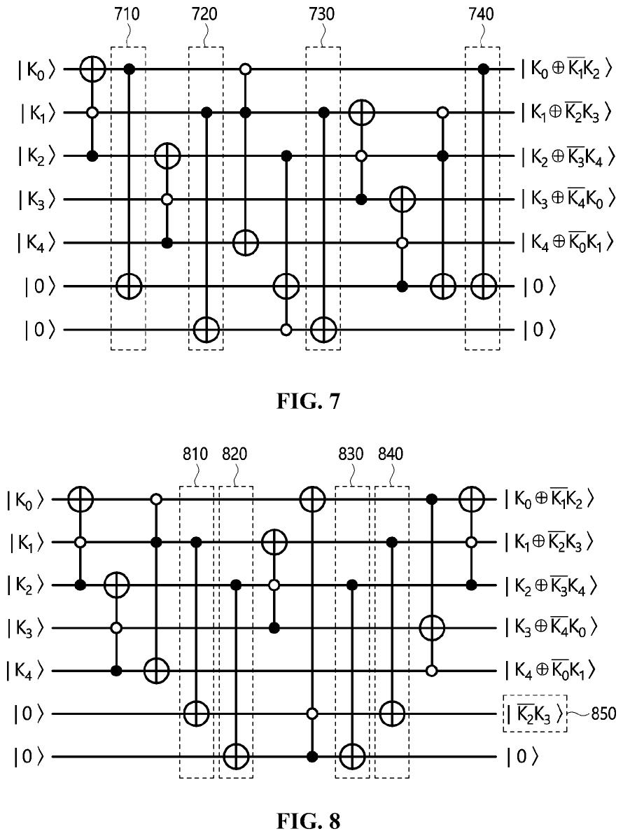

When a quantum circuit having a reduced Toffoli-depth is designed by taking the quantum circuit illustrated in FIG. 5 as an input quantum circuit according to the present disclosure, as described above, an output quantum circuit having the form illustrated in FIG. 7 may be generated.

Referring to FIG. 7, it can be seen that pieces of information containing the states of qubits of indices of 0 and 1 are transferred to work qubits through CNOT gates 710 to 740.

Here, according to the above-described permutation group theory, because the pieces of data information contained in the qubits having indices of 0, 1, and 2 are required to pass through the first MPT gate and the second MPT gate before passing through the fifth MPT gate, the first MPT gate and the second MPT gate should be placed before the third MPT gate and the fifth MPT gate.

Subsequently, an uncomputation step may be designed in order to initialize the added two work qubits.

Here, in order to detect whether the pieces of data information are input to the work qubits, gates that take the work qubits as target qubits may be checked. That is, when the pieces of information that are input to the work qubits by taking the work qubits as the target qubits are duplicated, the corresponding work qubits may be initialized to ‘0’.

These pieces of data information may be represented using Boolean algebra expressions, and whenever data information is input to the work qubit, the information currently contained therein may be detected by performing an XOR operation.

For example, Equation (9) relates to the first work qubit that receives the data information of index 0, and it can be seen that the first work qubit is initialized after passing through all of the gates.

$$( {K}_{0} ⊕ \overline{{K}_{1}} {K}_{2} ) ⊕ \overline{{K}_{1}} ( {K}_{2} ⊕ \overline{{K}_{3}} {K}_{4} ) ⊕ ( {K}_{1} ⊕ \overline{{K}_{2}} {K}_{3} ) ( {K}_{2} ⊕ \overline{{K}_{3}} {K}_{4} ) ⊕ ( {K}_{0} ⊕ \overline{{K}_{1}} {K}_{2} ) = 0 \qquad ( 9 )$$

Here, in the case of the first work qubit, an uncomputation step may be performed from the seventh MPT gate. For example, because the sixth MPT gate is used for generating another function value, it may correspond to a gate included in the computation step, rather than the uncomputation step.

Here, comparing the output quantum circuit illustrated in FIG. 7 with the input quantum circuit illustrated in FIG. 5, because the target point of the fifth gate that is processed in parallel is changed, the target point of the seventh MPT gate having the same arrangement is also changed.

Also, the data information within the qubit having an index of 1 may be input to the second work qubit. Here, because there is no operation process for the second work qubit before the operation of the fifth MPT gate is performed, the uncomputation step may be performed by merely arranging the CNOT gate 720 before the third MPT gate. That is, because the second work qubit is used as only the control part of the fifth MPT gate that is processed in parallel, the uncomputation step may be performed using only one CNOT gate.

Comparing the chi function quantum circuit illustrated in FIG. 5 with the circuit to which the two work qubits and the multiple CNOT gates 710 to 740 are added, as described above, a chi function quantum circuit, the Toffoli-depth of which is reduced to 6, may be designed.

Hereinafter, a process of generating an in-place version of a quantum circuit having a reduced Toffoli-depth by processing the fourth MPT gate and the fifth MPT gate illustrated in FIG. 5 in parallel according to the present disclosure will be described.

In the chi function quantum circuit illustrated in FIG. 5, the fourth MPT gate corresponds to a gate on the qubits having index values of 1, 2, and 3, and the fifth MPT gate corresponds to a gate on the qubits having index values of 0, 1, and 2. That is, because two indices are common to the fourth MPT gate and the fifth MPT gate, it is necessary to add at least two work qubits in order to process the fourth MPT gate and the fifth MPT gate in parallel.

Here, when a quantum circuit is designed according to the above-described logic applied to the pair comprising the third MPT gate and the fifth MPT gate, it can be seen that the uncomputation step cannot be perfectly designed, as illustrated in FIG. 8. Specifically, because the state of the qubit having an index of 1 is changed by the fourth MPT gate, the first work qubit can't be initialized.

Consequently, data information K₁ cannot be input to the first work qubit unless the Toffoli-count is increased.

Here, when it is intended to solve the problem of initializing the first work qubit by increasing the number of work qubits, an uncomputation step for initialization has to be performed also for the newly added work qubits. Therefore, the use of more work qubits does not necessarily ensure the design of an in-place version of a quantum circuit having a reduced Toffoli-depth.

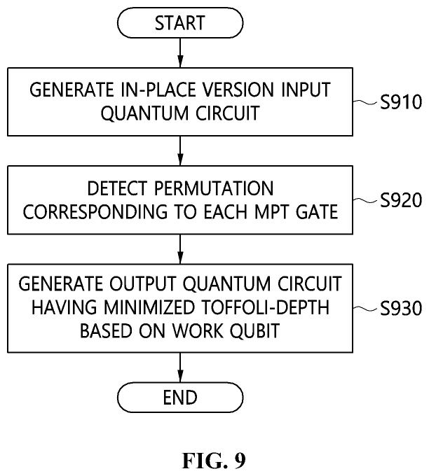

Hereinafter, an embodiment of the present disclosure for designing an in-place version of a quantum circuit having a reduced Toffoli-depth even in the case of FIG. 8 will be described with reference to FIG. 9.

FIG. 9 is a flowchart illustrating a method for quantum circuit design for Toffoli-depth reduction according to another embodiment of the present disclosure.

Referring to FIG. 9, in the method for quantum circuit design for Toffoli-depth reduction according to another embodiment of the present disclosure, an in-place version of an input quantum circuit is generated based on reversible function blocks forming a quantum circuit at step S910.

Here, when the input quantum circuit is generated, an increase in a Toffoli-count may be allowed.

Here, the in-place version of the input quantum circuit may be generated by inputting the index values of the respective reversible function blocks to data qubits.

Also, in the method for quantum circuit design for Toffoli-depth reduction according to another embodiment of the present disclosure, permutations corresponding to respective mixed polarity Toffoli gates included in the input quantum circuit are detected at step S920.

Also, in the method for quantum circuit design for Toffoli-depth reduction according to another embodiment of the present disclosure, the arrangement of the mixed polarity Toffoli gates is changed based on the permutations and work qubits such that the Toffoli-depth is minimized, whereby an output quantum circuit is generated at step S930. Here, the permutation may be converted into a product of transpositions.

Here, in the product of the transpositions, transpositions capable of being canceled out may be canceled out.

Here, the output quantum circuit may be generated in consideration of at least one of four design types for increasing time efficiency or space efficiency.

The four design types may include a first design type configured to minimize the Toffoli-depth regardless of the number of work qubits, a second design type configured to repeatedly generate function values of the reversible function blocks in consideration of the number of data qubits and the number of work qubits, a third design type configured to repeat the same permutation in consideration of the permutations and the flow of data information, and a fourth design type configured to additionally reduce a Toffoli-count in the output quantum circuit.

Here, in the second design type, the function values may be generated (n+m)/m times based on n data qubits and m work qubits.

Here, in the fourth design type, when the number of work qubits is equal to or greater than twice the number of data qubits, the work qubits may be initialized using a CNOT gate, and an intermediate value may be input to the initialized work qubits such that the CNOT gate is converted to the permutation corresponding to the mixed polarity Toffoli gate.

Here, when the input quantum circuit corresponds to a Measurement-Based Quantum Computation (MBQC) model, the output quantum circuit may be generated by further considering two MBQC-based design types.

Here, the two MBQC-based design types may include an MBQC-based first design type that makes the output value pair of an AND gate different from the input value pair of an AND^{†} gate and an MBQC-based second design type that generates an output value using an intermediate value generated by an AND gate.

Here, in a quantum circuit system configured to include the output quantum circuit, the initialized work qubits may be provided for the operation arranged after the output quantum circuit.

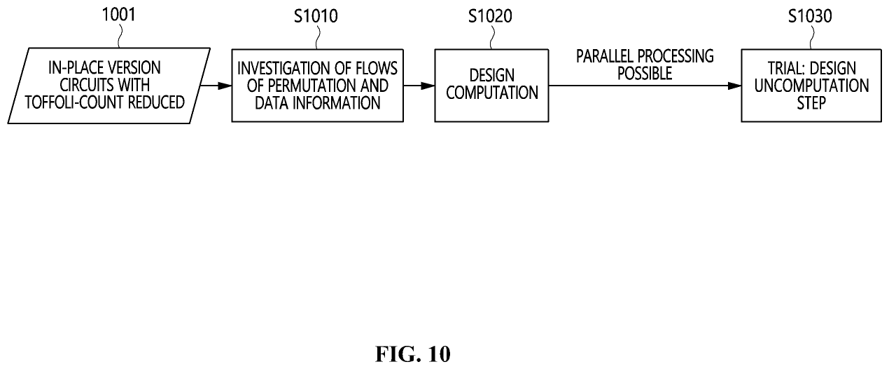

Here, the quantum circuit design method proposed through FIG. 9 relates to a method when an increase in a Toffoli-count is allowed, and may be represented in detail through the flowchart in FIG. 10.

Referring to FIG. 10, at a preprocessing step (S1010), various versions of an in-place version quantum circuit may be secured based on a given reversible function 1001. Here, the flows of gates (permutations) forming the respective in-place-version quantum circuits and the process of generating data information may be investigated.

Subsequently, a computation step may be designed at step S1020 such that a Toffoli-depth is minimized using as many work qubits as possible.

Here, the circuit may be designed such that all of the desired output values are quickly output without considering the process of initializing the work qubits. When step S1020 is finished, input values, output values, and intermediate values may be mixed in the states of the qubits.

Subsequently, using the flow of the permutations of the input circuits and the flow of the pieces of data information, an uncomputation step may be designed at step S1030 such that multiple flows are simultaneously processed in a single quantum circuit.

That is, the given reversible function 1001 may be implemented multiple times in the quantum circuit.

Here, how many times the reversible function 1001 has to be implemented may be determined in consideration of the number of used work qubits. For example, when the number of used data qubits is n and when the number of work qubits is m, the quantum circuit may be designed such that function values are generated repeatedly about (n+m)/n times.

When all of the above-described steps are passed through, all intermediate values disappear, and only the function values remain as the states of the qubits. Accordingly, the repeated function values may be finally initialized using CNOT gates.

Also, when the size of the domain and codomain of the given reversible function at the uncomputation step is 2n and when the number of used work qubits is equal to or greater than 2n, initializing the work qubits and copying the result value may be performed using the intermediate values and the output values. Through this process, the Toffoli-count may be reduced.

Hereinafter, taking a chi function of an SHA3-256 hash function algorithm as an example, the process of designing a chi function quantum circuit having a reduced Toffoli-depth using the method illustrated in FIG. 9, that is, the process of designing a chi function quantum circuit having a reduced Toffoli-depth when an increase in the Toffoli-count is allowed, will be described in detail by classifying the process into four types.

The first type may correspond to designing a chi function quantum circuit so as to maximally reduce a Toffoli-depth using a sufficiently large number of work qubits.

First, in order to design the computation step of the chi function quantum circuit, it is necessary to investigate the permutations of input quantum circuits and the flow of pieces of data information. Through the flows, the process by which function values are obtained may be understood, and the minimum Toffoli-depth required for obtaining the respective function values may be checked.

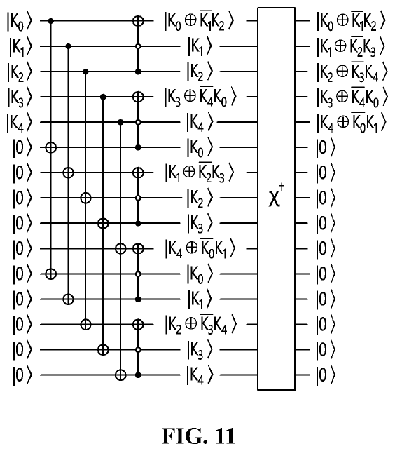

Here, because all of the function values of the chi function have the multiplicative complexity of 1, the computation step may be designed using only a sufficient number of work qubits and five MPT gates, as illustrated in FIG. 11.

Here, a total of 10 work qubits are used in the chi function quantum circuit illustrated in FIG. 11.

The second type may correspond to designing a quantum circuit such that desired function values of a reversible function are generated about (n+m)/m times when it is assumed that the number of data qubits is n and the number of work qubits is m.

For example, in the case of the chi function, the number of data qubits and the number of work qubits are 5 and 10, respectively, so three duplicate pairs of chi function values may be generated. Referring to FIG. 11, the generated function value pairs may be detected as shown in Equation (10).

$${K}_{0} ⊕ \overline{{K}_{1}} {K}_{2} , {K}_{1} ⊕ \overline{{K}_{2}} {K}_{3} , {K}_{2} ⊕ \overline{{K}_{3}} {K}_{4} , {K}_{3} ⊕ \overline{{K}_{4}} {K}_{0} , {K}_{4} ⊕ \overline{{K}_{0}} {K}_{1} \qquad ( 10 )$$

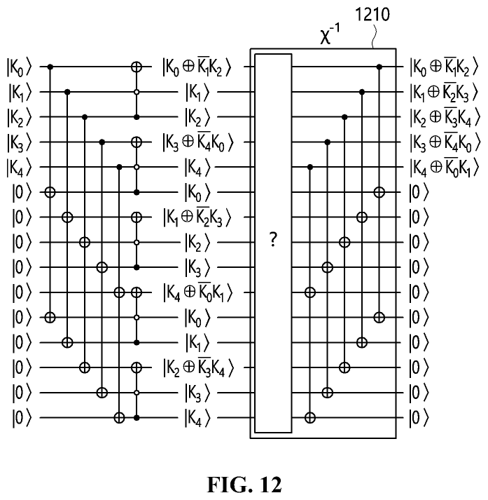

As in Equation (10), the duplicate pairs may be eliminated through CNOT gates 1210, as illustrated in FIG. 12.

The third type may correspond to designing a quantum circuit such that the same permutation appears multiple times by detecting the permutation of an input quantum circuit and the flow of data information.

As described above, a chi function may be implemented as 15 different versions of an in-place version quantum circuit having a Toffoli-count of 7. Here, the flow of the permutations in the generated quantum circuits has to be arranged such that they are processed in parallel, and the Toffoli-count to be increased may be estimated before the arrangement.

For example, in the case of the chi-function quantum circuit illustrated in FIG. 5, the Toffoli-count is 5, and 28 transpositions are used. When it is intended to represent this chi function three times, it may be expected that about 21 MPT gates are to be used.

Also, Equation (8) represents permutations corresponding to the MPT gates used in the chi function quantum circuit illustrated in FIG. 5. Assuming that the permutations corresponding to the first to fourth MPT gates and the sixth MPT gate are referred to as P₀, P₂, P₄, P₁, and P₃ based on the indices that are set in consideration of the target points of the respective MPT gates, the permutations of the chi function quantum circuit illustrated in FIG. 5 may be arranged in the order illustrated in Equation (11):

$${P}_{0} -> {P}_{2} -> {P}_{4} -> {P}_{1} -> {P}_{0} -> {P}_{3} -> {P}_{0} \qquad ( 11 )$$

Here, when ‘P₀->P₃->P₀’ in the back part of the chi function quantum circuit in Equation (11) is converted into permutations, the permutations may correspond to (4,5) (12,13) (20,21) (28,29), (1,9) (3,11) (5,13) (7,15), (4,5) (12,13) (20,21) (28,29).

Here, two permutations, each being composed of (20,21) (28,29), may cancel out each other, but two permutations, each being composed of (4,5) (12,13), may not cancel out each other because (5,13) is present between the two permutations. For example, one of the two permutations, each being composed of (20,21) (28,29), may be canceled out by (4,5) (12,13) of P₀ located at the front of the quantum circuit. Consequently, when (1,9) (3,11) (7,15) are ignored, (4,5) (12,13) (5,13) remain, and these may correspond to (4,5,12,13).

That is, because two P₀ permutations are used in the back part of the chi function quantum circuit, (5,4,13,12) is changed to (4,5,12,13), whereby the desired chi function quantum circuit is implemented.

Here, if (4,5,12,13) is decomposed into (4,5) (12,13) (5,13) (4,5) (12,13) (4,5) (12,13), these may be represented using multiple MPT gates in a quantum circuit.

In this way, the multiple cycles forming the chi function are decomposed into a product of transpositions, whereby a hint for designing a quantum circuit having a reduced Toffoli-depth may be obtained.

Here, the chi function may be represented using a product of 20 transpositions, and the chi function quantum circuit illustrated in FIG. 5 is expressed as 28 transpositions. Therefore, when the total number of qubits is 15, at most five MPT gates may be processed in parallel. Also, when the chi function is represented three times, about 21 MPT gates are expected to be used, so whether a quantum circuit can be designed using 25 MPT gates corresponding to a multiple of 5 may be determined.

Assuming that 25 MPT gates are used, each of the MPT gates is represented using four transpositions, so they may be represented using a total of 100 transpositions. Also, because the chi function needs to be implemented three times, the design may be made such that 40 transpositions are canceled out.

Equation (12) represents the gates that are used to decompose 4-cycles included in the permutations of the chi function illustrated in Equation (7).

Here, as in the example in which three P₀ permutations and one P₃ permutation are used in order to decompose (4,5,12,13), gates that are used in order to decompose the cycles forming various in-place version input quantum circuits may be checked.

$$( 4 , 5 , 12 , 13 ) : {P}_{0} -> {P}_{0} -> {P}_{3} -> {P}_{0} \\ ( 1 , 9 , 3 , 11 ) : {P}_{3} -> {P}_{3} -> {P}_{1} -> {P}_{3} \\ ( 2 , 18 , 6 , 22 ) : {P}_{4} -> {P}_{4} -> {P}_{2} -> {P}_{4} \\ ( 8 , 10 , 24 , 26 ) : {P}_{1} -> {P}_{1} -> {P}_{4} -> {P}_{1} \\ ( 16 , 20 , 17 , 21 ) : {P}_{2} -> {P}_{2} -> {P}_{0} -> {P}_{2} \qquad ( 12 )$$

Also, the order information of MPT gates for quantum circuit design may be acquired using Boolean algebra expressions obtained from the flow of data information.

For example, in various in-place version chi function quantum circuits, multiple intermediate values are generated in the circuit, and the flow of gates required for generation of the intermediate values may be represented as shown in Equation (13):

$$( {K}_{0} ⊕ \overline{{K}_{1} {K}_{3}} , {K}_{4} ) : {P}_{0} \& {P}_{2} \to {P}_{0} \\ ( {K}_{1} ⊕ \overline{{K}_{2} {K}_{4}} , {K}_{0} ) : {P}_{1} \& {P}_{3} \to {P}_{1} \\ ( {K}_{2} ⊕ \overline{{K}_{3} {K}_{0}} , {K}_{1} ) : {P}_{2} \& {P}_{4} \to {P}_{2} \\ ( {K}_{3} ⊕ \overline{{K}_{4} {K}_{1}} , {K}_{2} ) : {P}_{3} \& {P}_{0} \to {P}_{3} \\ ( {K}_{4} ⊕ \overline{{K}_{0} {K}_{2}} , {K}_{3} ) : {P}_{4} \& {P}_{1} \to {P}_{4} \qquad ( 13 )$$

Accordingly, MPT gates are suitably arranged based on the decomposition of each cycle that can be obtained in multiple reversible input circuits, such as that shown in Equation (12), and on the order of the permutations required for generating intermediate values as shown in Equation (13), whereby a quantum circuit having a reduced Toffoli-depth may be designed.

The fourth type may correspond to designing a quantum circuit such that a Toffoli-count is also reduced in a quantum circuit designed to reduce a Toffoli-depth.

To this end, if the number of work qubits used in the computation step of a quantum circuit is equal to or greater than twice the number of data qubits, the work qubits are initialized using CNOT gates, and output values are input to the initialized work qubits, whereby second function value pairs may be generated. This is possible because the work qubits can have the input values or the intermediate values.

For example, it may be assumed that the number of work qubits used in the chi function quantum circuit is 10 and that five different input values are evenly assigned after the computation step. Here, the values input to the five work qubits may be initialized using CNOT gates, and the output values, that is, intermediate values, may be input to the initialized five work qubits.

$$( {K}_{0} ⊕ \overline{{K}_{1}} {K}_{2} , {K}_{0} , {K}_{0} ) \to ( {K}_{0} ⊕ \overline{{K}_{1}} {K}_{2} , 0 , {K}_{0} ) \to ( {K}_{0} ⊕ \overline{{K}_{1}} {K}_{2} , {K}_{0} ⊕ \overline{{K}_{1}} {K}_{2} , {K}_{0} ) \qquad ( 14 )$$

Referring to Equation (14), because the CNOT gates used to initialize the work qubits can make the effect of MPT gates, it may be interpreted that the CNOT gates represent permutations corresponding to the MPT gates. Using this idea, the Toffoli-count may be reduced.

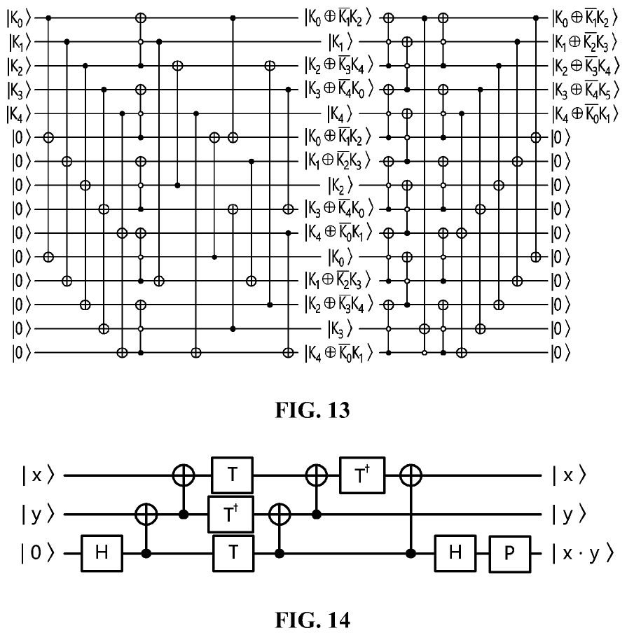

FIG. 13 illustrates a quantum circuit that is designed using a total of 25 Toffoli gates by applying the method described through the above first to fourth types.

Referring to FIG. 13, the Toffoli-count is decreased by 5 using the Toffoli-count reduction method of the fourth type, and it can be seen that a quantum circuit having a Toffoli-depth of 4 and a Toffoli-count of 20 is designed.

Here, in the case of the MPT gates illustrated in FIG. 13, each five MPT gates form one Toffoli-depth. That is, in the chi function quantum circuit illustrated in FIG. 5, seven MPT gates are represented using 28 transpositions, and in the chi-function quantum circuit illustrated in FIG. 13, 20 MPT gates and 30 CNOT gates are represented using 100 transpositions.

Hereinafter, a design method capable of reducing a Toffoli-depth for an in-place version of a quantum circuit based on MBQC will be described in detail with reference to FIGS. 14 to 16.

The MBQC model corresponds to a design technique capable of reducing the design cost or the total execution time of a quantum circuit by installing a measuring device in the intermediate part of the quantum circuit as well as in the end part of the quantum circuit. To this end, the MBQC model may use an AND gate and an AND^{†} gate instead of a Toffoli gate.

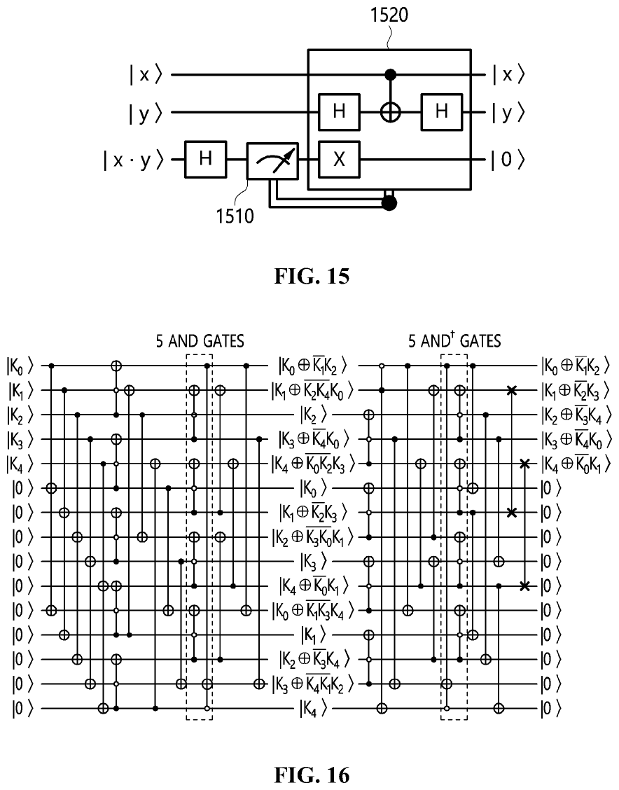

The gate illustrated in FIG. 14 is an AND gate, and the gate illustrated in FIG. 15 is an AND^{†} gate.

The AND gate illustrated in FIG. 14 may be implemented as a gate having a Toffoli-depth of 2 if there is no help of work qubits. That is, a product of two binary input values (x, y) may be returned to the target part of the AND gate.

Here, the largest difference between the Toffoli gate and the AND gate is that the state of a qubit on the target line of the AND gate should be initialized to FALSE (0) in the input value. Symmetrically, the input value of the AND^{†} gate is (x, y, x·y), the output value thereof is (x, y, 0), and the target part may be initialized to FALSE (0).

Here, the measuring device 1510 is used in the AND^{†} gate, as illustrated in FIG. 15.

For example, in the AND^{†} gate, whether to activate specific gates 1520 may be determined depending on the result in the measuring device 1510. In FIG. 15, the measuring device 1510 is located after the H gate, and when the measurement result in the measuring device 1510 is TRUE (1), the operation of the specific gates 1520, including two H gates, an X gate, and a CNOT gate, may be performed. When the measurement result in the measurement device 1510 is FALSE (0), the operation of the specific gates 1520 may not be performed.

The present disclosure intends to propose two types of ideas capable of reducing a Toffoli-depth when the MBQC model is used.

The first type using the MBQC model is to design a circuit such that the output value pair of an AND gate differs from the input value pair of an AND^{†} gate.

Generally, when the output value pair of the AND gate is (x, y, x·y) and when the input value pair of the AND^{†} gate is (x, y′, x·y′), the target part of the AND^{†} gate is not initialized. However, when (x·y=x·y′) holds, the target part of the AND^{†} gate may be initialized.

This method is applied for two reasons. The first reason is due to constraints on the input values of the AND gate, and the second reason is that only final function values and a product of the function values should remain in the end part of the quantum circuit in order to generate an in-place version of a circuit.

Accordingly, the product of the output values (or the intermediate values) may be output using values other than the output values of the AND gate. Through this process, the work qubits located in the target part may be initialized, and some Toffoli-depths may be converted into AND-depths (the number of nonparallel processing of AND gates or AND^{†} gates).

Here, because all of the function values of a chi function have the multiplicative complexity of 1, if a sufficient number of work qubits is added, five function values may be generated using only ten CNOT gates and five MPT gates.

That is, FIG. 16 illustrates an MBQC-model-based in-place version chi function quantum circuit having a reduced Toffoli-depth, and the computation step thereof may be designed to be the same as the quantum circuit illustrated in FIG. 13. However, it can be seen that MBQC is applied to the uncomputation step for initialization of the work qubits.

Here, in (x, y′, x·y′), which is the input value pair of the AND^{†} gate, (x, y′) should be function values and (x·y′) should be the product of the function values. Also, in (x, y, x·y), which is the output value pair of the AND gate, (y) should not be the function value.

For example, when the input values of the AND gate are K̅₀̅ and K₁⊕K̅₂̅K₃, the intermediate value K̅₀̅K₁⊕K̅₀̅K̅₂̅K₃ may be returned in the target part, and this value is the same as (K̅₀̅⊕K̅₁̅K₂) (K₁⊕K̅₂̅K₃).

Also, the second type using the MBQC model is to generate output values using intermediate values generated using an AND gate. Because the output values generated in this way are duplicated, they may cancel out through CNOT gates located in the end part of the quantum circuit. The process of generating output values using the intermediate values generated in the AND gate may correspond to Equation (15):

$$( {K}_{4} ⊕ \overline{{K}_{0}} {K}_{1} ) ⊕ ( {K}_{0} {K}_{1} ⊕ \overline{{K}_{0} {K}_{2}} {K}_{3} ) = {K}_{4} ⊕ \overline{{K}_{0} {K}_{2}} {K}_{3} ⇒ {K}_{2} ⊕ ( \overline{{K}_{3}} ⊕ \overline{{K}_{4}} {K}_{0} ) ( {K}_{4} ⊕ \overline{{K}_{0} {K}_{2}} {K}_{3} ) = {K}_{2} ⊕ \overline{{K}_{3}} {K}_{4} \qquad ( 15 )$$

When the ideas of the first and second types using the MBQC model are used, an MBQC-based in-place version quantum circuit having a reduced Toffoli-depth may be designed, as illustrated in FIG. 16.

Here, comparing the quantum circuit illustrated in FIG. 16 with that illustrated in FIG. 13, it can be seen that half the 20 MPT gates are replaced with AND gates or AND^{†} gates. That is, the depth of 2 of the Toffoli-depth of 4 in the quantum circuit illustrated in FIG. 16 corresponds to the depth formed through the AND gates or the AND^{†} gates. Here, a total of ten work qubits are used for both the two quantum circuits.

Also, comparing the two quantum circuits using permutation group theory, the quantum circuit illustrated in FIG. 16 uses only five CNOT gates in the end part thereof, so it can be seen that the chi reversible function is implemented twice in the circuit.

Here, considering that the permutation group theory is applied through the AND gate and the AND^{†} gate, like MPT gates, the 20 composite gates in FIG. 16 may be represented using 80 transpositions. Here, 40 transpositions may cancel out according to the above-mentioned logic, and the chi reversible function may be implemented twice using the remaining 40 transpositions.

Here, the arrangement of the MPT gates and the AND gates may be expressed as shown in Equation (16) by applying the theory described through Equation (12) and Equation (13).

$$( 1 , 9 , 3 , 11 ) ( 8 , 10 ) ( 24 , 26 ) ( 25 , 27 ) ( 5 , 13 ) ( 7 , 15 ) ( 4 , 5 ) ( 12 , 13 ) ( 20 , 21 ) ( 28 , 29 ) \\ {P}_{0} ( \& {P}_{3} ) -> {P}_{3} -> {P}_{1} -> {P}_{3}^{- 1} ( = {P}_{3} ) \qquad ( 16 )$$

Referring to Equation (16), based on P₀ MPT gate located on the leftmost side of the quantum circuit illustrated in FIG. 16, the order of the remaining permutations may be detected. Here, considering the order of other permutations, it can be seen that the chi function is implemented twice in the quantum circuit illustrated in FIG. 16. Also, because the chi function is implemented twice, five work qubits may be initialized using five CNOT gates in the end part of the quantum circuit illustrated in FIG. 16. For reference, the two last gates in the quantum circuit illustrated in FIG. 16 correspond to SWAP gates, and these gates merely change the positions of qubits and incur no design cost at the logic level.

According to the present disclosure, the Toffoli depth of a given in-place version of a quantum circuit is reduced, whereby the quantum circuit may be converted into a more time-efficient in-place version of a quantum circuit.

Also, the present disclosure enables work qubits assisting an operation process to be initialized in an in-place version of a quantum circuit and provides the initialized work qubits to a subsequent circuit operation, thereby more efficiently using the work qubits.

As described above, the method for quantum circuit design for Toffoli-depth reduction according to the present disclosure is not limitedly applied to the configurations and operations of the above-described embodiments, but all or some of the embodiments may be selectively combined and configured, so the embodiments may be modified in various ways.

What is claimed is:

1. A method for quantum circuit design, comprising:
generating an in-place version of an input quantum circuit having a minimized Toffoli-count based on reversible function blocks forming a quantum circuit;
detecting permutations corresponding to respective mixed polarity Toffoli gates included in the input quantum circuit;
searching for a pair of gates capable of being processed in parallel, among the mixed polarity Toffoli gates, based on the permutations; and
generating an output quantum circuit, a Toffoli-depth of which is reduced compared to the input quantum circuit, by changing positions of the mixed polarity Toffoli gates such that the pair of gates is processed in parallel based on work qubits.

2. The method of claim 1, wherein a number of work qubits is set in consideration of a number of qubit positions common to the pair of gates.

3. The method of claim 1, wherein searching for the pair of gates comprises converting the permutation into a product of transpositions and searching for the pair of gates based on the product of the transpositions.

4. The method of claim 1, wherein generating the output quantum circuit includes
adding a first-type CNOT gate in a section in which the pair of gates is processed in parallel in order to input information required for forming the permutation to the work qubits; and
adding a second-type CNOT gate for initialization of the work qubits.

5. The method of claim 4, wherein the work qubits are initialized through the second-type CNOT gate after an operation by the mixed polarity Toffoli gates is completed.

6. The method of claim 1, wherein the in-place version of the input quantum circuit is generated by inputting index values of the respective reversible function blocks to data qubits.

7. The method of claim 1 wherein, in a quantum circuit system configured to include the output quantum circuit, initialized work qubits are provided for an operation arranged after the output quantum circuit.

8. A method for quantum circuit design, comprising:
generating an in-place version of an input quantum circuit based on reversible function blocks forming a quantum circuit;
detecting permutations corresponding to respective mixed polarity Toffoli gates included in the input quantum circuit; and
generating an output quantum circuit by changing arrangement of the mixed polarity Toffoli gates based on the permutations and work qubits such that a Toffoli-depth is minimized,
wherein an increase in a Toffoli-count is allowed when the input quantum circuit is generated.

9. The method of claim 8, wherein generating the output quantum circuit includes
converting the permutation into a product of transpositions; and
cancelling out transpositions capable of being canceled out in the product of the transpositions.

10. The method of claim 9, wherein generating the output quantum circuit comprises generating the output quantum circuit in consideration of at least one of four design types for increasing time efficiency or space efficiency.

11. The method of claim 10, wherein the four design types include a first design type that minimizes the Toffoli-depth regardless of a number of work qubits, a second design type that repeatedly generates function values of the reversible function blocks in consideration of a number of data qubits and a number of work qubits, a third design type that makes an identical permutation repeated in consideration of the permutations and a flow of data information, and a fourth design type that additionally reduces the Toffoli-count in the output quantum circuit.

12. The method of claim 11, wherein the second design type is configured such that the function values are generated (n+m)/m times based on n data qubits and m work qubits.

13. The method of claim 11, wherein the fourth design type is configured such that, when the number of work qubits is equal to or greater than twice the number of data qubits, the work qubits are initialized using a CNOT gate and an intermediate value is input to the initialized work qubits so that the CNOT gate is converted to the permutation corresponding to the mixed polarity Toffoli gate.

14. The method of claim 10, wherein, when the input quantum circuit corresponds to a Measurement-Based Quantum Computation (MBQC) model, the output quantum circuit is generated by further considering two MBQC-based design types.

15. The method of claim 14, wherein the two MBQC-based design types include an MBQC-based first design type configured to make an output value pair of an AND gate different from an input value pair of an AND^{†} gate and an MBQC-based second design type configured to generate an output value using an intermediate value generated using an AND gate.

16. The method of claim 8, wherein the in-place version of the input quantum circuit is generated by inputting index values of the respective reversible function blocks to data qubits.

17. The method of claim 8, wherein, in a quantum circuit system configured to include the output quantum circuit, initialized work qubits are provided for an operation arranged after the output quantum circuit.
